(19) United States
(12) Patent Application Publication
(10) Pub. No.: US 2025/0107347 A1
(43) Pub. Date: Mar. 27, 2025

(54) DISPLAY PANEL AND METHOD FOR MANUFACTURING THE SAME

(71) Applicant: Samsung Display Co., Ltd., Yongin-si (KR)

(72) Inventors: JOONYONG PARK, Yongin-si (KR); SUKYOUNG YANG, Yongin-si (KR); DONGMIN LEE, Yongin-si (KR); HYUNEOK SHIN, Yongin-si (KR)

(21) Appl. No.: 18/814,974

(22) Filed: Aug. 26, 2024

(30) Foreign Application Priority Data
Sep. 26, 2023 (KR) 10-2023-0128803

(51) Int. Cl. H10K 59/122; H10K 59/12

(52) U.S. Cl. CPC H10K 59/122; H10K 59/1201

(57) ABSTRACT

A display panel includes: a base layer; a pixel-defining film on the base layer, and having a light-emitting opening; a partition wall having a partition wall opening overlapping with the light-emitting opening, and including a first partition wall layer on the pixel-defining film, and a second partition wall layer on the first partition wall layer; a light-emitting element at least partially located in the partition wall opening, and including an anode, an intermediate layer, and a cathode in contact with the partition wall; and a sacrificial pattern between the first partition wall layer and the second partition wall layer, and having a sacrificial opening overlapping with the partition wall opening.

### CROSS-REFERENCE TO RELATED APPLICATIONS

The present application claims priority to and the benefit of Korean Patent Application No. 10-2023-0128803, filed on Sep. 26, 2023, in the Korean Intellectual Property Office, the entire disclosure of which is incorporated by reference herein.

### BACKGROUND

### 1. Field

Aspects of embodiments of present disclosure relate to a display panel having improved display quality, and a method for manufacturing the display panel.

### 2. Description of the Related Art

A display device, such as a television, a monitor, a smartphone, and a tablet computer, includes a display panel for displaying an image to a user. Various suitable panels, such as a liquid crystal display panel, an organic light-emitting display panel, an electro-wetting display panel, and an electrophoretic display panel, are being developed as the display panel.

The organic light-emitting display panel may include an anode, a cathode, and a light-emitting pattern. The light-emitting pattern may be separated for each light-emitting region, and the cathode may supply a common voltage to each light-emitting region.

The above information disclosed in this Background section is for enhancement of understanding of the background of the present disclosure, and therefore, it may contain information that does not constitute prior art.

### SUMMARY

Embodiments of present disclosure may be directed to a display panel having improved display quality from among display panels in which a light-emitting element is formed without using a metal mask, and a method for manufacturing the display panel.

According to one or more embodiments of the present disclosure, a display panel includes: a base layer; a pixel-defining film on the base layer, and having a light-emitting opening; a partition wall having a partition wall opening overlapping with the light-emitting opening, and including a first partition wall layer on the pixel-defining film, and a second partition wall layer on the first partition wall layer; a light-emitting element at least partially located in the partition wall opening, and including an anode, an intermediate layer, and a cathode in contact with the partition wall; and a sacrificial pattern between the first partition wall layer and the second partition wall layer, and having a sacrificial opening overlapping with the partition wall opening.

In an embodiment, the sacrificial pattern may have an undercut shape with respect to the partition wall.

In an embodiment, the first partition wall layer of the partition wall may have an undercut shape with respect to the second partition wall layer.

In an embodiment, the first partition wall layer may include a first side surface defining a first region, the sacrificial pattern may include a second side surface defining a second region, the second partition wall layer may include a third side surface defining a third region, and the first to third regions may be integral with each other in a thickness direction of the base layer.

In an embodiment, the second side surface of the sacrificial pattern may be recessed in a direction away from the partition wall opening more than the first side surface of the first partition wall layer and the third side surface of the second partition wall layer.

In an embodiment, in a plan view, the second side surface of the sacrificial pattern may overlap with the first partition wall layer and the second partition wall layer.

In an embodiment, a width of the second region in a first direction may be greater than a width of the first region in the first direction and a width of the third region in the first direction.

In an embodiment, the display panel may further include a lower sacrificial pattern between the anode and the pixel-defining film, and having a lower sacrificial opening overlapping with the light-emitting opening.

In an embodiment, the pixel-defining film may include: a first pixel-defining film on the base layer, and including a first inner side surface defining a first pixel opening of the light-emitting opening; and a second pixel-defining film on the first pixel-defining film, and including a second inner side surface defining a second pixel opening of the light-emitting opening.

In an embodiment, a width of the first pixel opening in a first direction may be equal to or smaller than a width of the second pixel opening in the first direction. In an embodiment, the cathode may be spaced from the sacrificial pattern.

According to one or more embodiments of the present disclosure, a display panel includes: a base layer; a pixel-defining film on the base layer, and having a light-emitting opening; a partition wall having a partition wall opening overlapping with the light-emitting opening, and including a first partition wall layer on the pixel-defining film, and a second partition wall layer on the first partition wall layer; a light-emitting element at least partially located in the partition wall opening, and including an anode, an intermediate layer, and a cathode in contact with the partition wall; a sacrificial pattern between the first partition wall layer and the second partition wall layer, and including a transparent conductive oxide; and a lower sacrificial pattern between the anode and the pixel-defining film, and including a transparent conductive oxide.

In an embodiment, the lower sacrificial pattern may have a lower sacrificial opening overlapping with the light-emitting opening, and the sacrificial pattern may have a sacrificial opening overlapping with the partition wall opening.

In an embodiment, the sacrificial pattern may have an undercut shape with respect to the partition wall.

In an embodiment, the first partition wall layer may include a first side surface defining a first region, the sacrificial pattern may include a second side surface defining a second region, and the second partition wall layer may include a third side surface defining a third region. The first to third regions may be integral with each other in a thickness direction of the base layer, and the second side surface of the sacrificial pattern may be recessed in a direction away from the partition wall opening more than the first side surface of the first partition wall layer and the third side surface of the second partition wall layer.

In an embodiment, in a plan view, the second side surface of the sacrificial pattern may overlap with the first partition wall layer and the second partition wall layer. In an embodiment, the cathode may be spaced from the sacrificial pattern.

According to one or more embodiments of the present disclosure, a method for manufacturing a display panel, includes: providing a preliminary display panel including a base layer, and an anode, a lower sacrificial layer, and a first preliminary pixel-defining film disposed on the base layer; forming a first pixel-defining film by etching the first preliminary pixel-defining film; sequentially depositing, on the first pixel-defining film, a second preliminary pixel-defining film, a first preliminary partition wall layer, a sacrificial layer, and a second preliminary partition wall layer; and forming a second pixel-defining film, a partition wall, and a sacrificial pattern by etching the second preliminary pixel-defining film, the first preliminary partition wall layer, the sacrificial layer, and the second preliminary partition wall layer.

In an embodiment, the forming of the second pixel-defining film, the partition wall, and the sacrificial pattern may include: etching the second preliminary partition wall layer; etching the sacrificial layer; etching the first preliminary partition wall layer; forming the partition wall having a partition wall opening by etching the first preliminary partition wall layer and the second preliminary partition wall layer; forming the second pixel-defining film by etching the second preliminary pixel-defining film; and forming the sacrificial pattern by etching the sacrificial layer.

In an embodiment, the forming of the sacrificial pattern by etching the sacrificial layer may include forming a lower sacrificial pattern by etching the lower sacrificial layer.

In an embodiment, the method may further include: forming a light-emitting pattern in the partition wall opening; forming, in the partition wall opening, a cathode in contact with the partition wall and spaced from the sacrificial pattern; and forming an inorganic lower encapsulation pattern in contact with the sacrificial pattern.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1A is a perspective view of a display device according to an embodiment of the present disclosure;

FIG. 1B is an exploded perspective view of a display device according to an embodiment of the present disclosure;

FIG. 2 is a cross-sectional view of a display module according to an embodiment of the present disclosure;

FIG. 3 is a plan view of a display panel according to an embodiment of the present disclosure;

FIG. 4 is a partially enlarged plan view of a display region of a display panel according to an embodiment of the present disclosure;

FIG. 5 is a cross-sectional view of a display panel taken along the line I-I′ in FIG. 3 according to an embodiment of the present disclosure; and

FIGS. 6A-6L are cross-sectional views illustrating some operations of a method for manufacturing a display panel according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

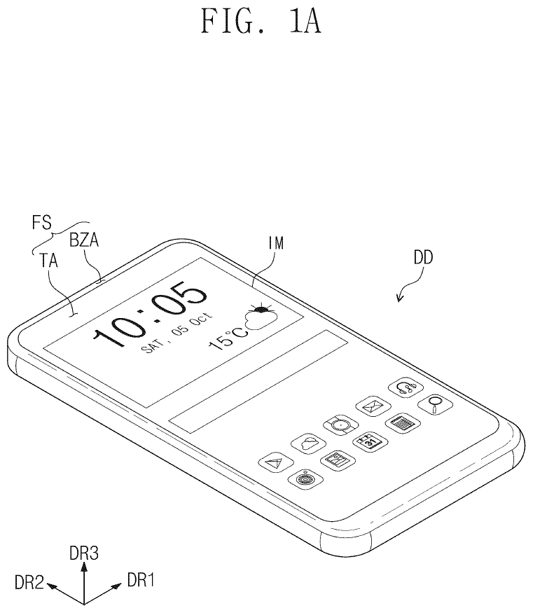

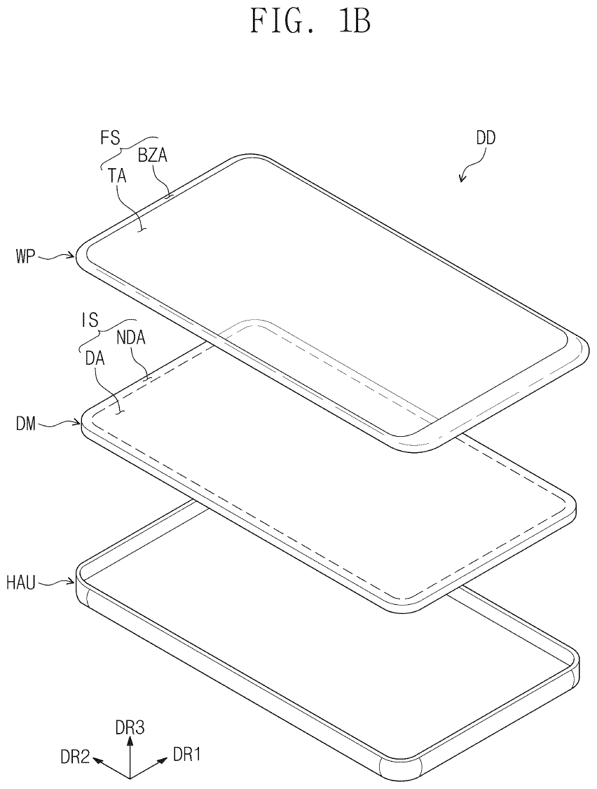

FIG. 1A is a perspective view of a display device DD according to an embodiment of the present disclosure. FIG. 1B is an exploded perspective view of the display device DD according to an embodiment of the present disclosure.

In an embodiment, the display device DD may be a large-sized electronic device, such as a television, a monitor, or a billboard. In an embodiment, the display device DD may be a small-sized and/or a medium-sized electronic device, such as a personal computer, a notebook computer, a private digital terminal, a car navigation unit, a game console, a smartphone, a tablet computer, or a camera. However, the present disclosure is not limited thereto, and the display device DD may be adopted to other suitable display devices. FIGS. 1A and 1B illustrate that the display device DD is a smartphone as a representative example.

Referring to FIGS. 1A and 1B, the display device DD may display an image IM toward a third direction DR3 on a display surface FS parallel to or substantially parallel to each of a first direction DR1 and a second direction DR2. The image IM may include a static image as well as a dynamic image. FIG. 1A illustrates a clock window and icons as a representative example of the image IM. The display surface FS on which the image IM is displayed may correspond to the front surface of the display device DD.

In the present embodiment, the front surface (e.g., an upper surface) and the rear surface (e.g., a lower surface) of each member are defined on the basis of the direction in which the image IM is displayed. The front surface and the rear surface are opposite to each other in the third direction DR3, and the normal direction of each of the front surface and the rear surface may be parallel to or substantially parallel to the third direction DR3. The directions indicated by the first to third directions DR1, DR2, and DR3 are relative concepts, and may be variously modified to other suitable directions. In the present specification, “on a plane” and “in a plan view” may mean when viewed in the third direction DR3.

The display device DD may include a window WP, a display module (e.g., a display or a touch display) DM, and a housing HAU. The window WP and the housing HAU may be connected to (e.g., coupled to or attached to) each other to constitute an exterior of the display device DD.

The window WP may include an optically transparent insulating material. For example, the window WP may include glass or plastic. The front surface of the window WP may define the display surface FS of the display device DD. The display surface FS may include a transmission region TA and a bezel region BZA. The transmission region TA may be an optically transparent region. For example, the transmission region TA may be a region having a visible light transmittance of about 90% or more.

The bezel region BZA may be a region having a relatively lower light transmittance than that of the transmission region TA. The bezel region BZA may define a shape of the transmission region TA. The bezel region BZA may be adjacent to the transmission region TA, and may surround (e.g., around a periphery of) the transmission region TA. However, the present disclosure is not limited thereto, and the bezel region BZA of the window WP may be omitted as needed or desired. The window WP may include at least any one functional layer of an anti-fingerprint layer, a hard-coating layer, or an anti-reflective layer, but the present disclosure is not limited to any particular embodiment.

The display module DM may be disposed on a lower portion (e.g., a lower surface) of the window WP. The display module DM may be a structure that generates or substantially generates the image IM. The image IM generated by the display module DM is displayed on a display surface IS of the display module DM, and may be viewed by an external user through the transmission region TA.

The display module DM may include a display region DA and a non-display region NDA. The display region DA may be a region activated in response to an electrical signal. The non-display region NDA may be adjacent to the display region DA. The non-display region NDA may surround (e.g., around a periphery of) the display region DA. The non-display region NDA may be a region covered by the bezel region BZA, and may not be viewed from the outside.

The housing HAU may be connected to (e.g., coupled to or attached to) the window WP. The housing HAU may be connected to (e.g., coupled to or attached to) the window WP to supply an inner space (e.g., a predetermined inner space). The display module DM may be accommodated in the inner space.

The housing HAU may include a suitable material having a relatively high rigidity. For example, the housing HAU may include glass, plastic, or a metal, or a plurality of frames and/or plates composed of a suitable combination thereof. The housing HAU may stably protect the configurations and structures of the display device DD accommodated in the inner space from an external impact.

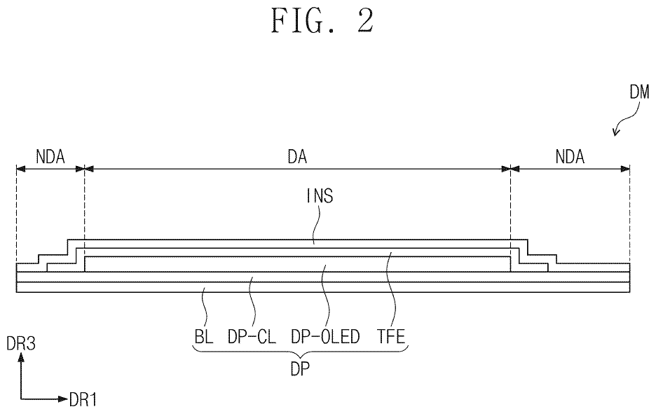

FIG. 2 is a cross-sectional view of the display module DM according to an embodiment of the present disclosure.

Referring to FIG. 2, the display module DM may include a display panel DP and an input sensor INS. The display device DD (e.g., see FIG. 1A) according to an embodiment of the present disclosure may further include a protective member disposed on a lower surface of the display panel DP, or an anti-reflective member and/or a window member disposed on an upper surface of the input sensor INS.

The display panel DP may be a light-emitting display panel. However, the present disclosure is not limited thereto. For example, the display panel DP may be an organic light-emitting display panel, or an inorganic light-emitting display panel. A light-emitting layer in the organic light-emitting display panel may include an organic light-emitting material. A light-emitting layer in the inorganic light-emitting display panel may include a quantum dot, a quantum rod, or a micro-LED. Hereinafter, the display panel DP may be described in more detail in the context of the organic light-emitting display panel.

The display panel DP may include a base layer BL, a circuit element layer DP-CL disposed on the base layer BL, a display element layer DP-OLED, and a thin-film encapsulation layer TFE. The input sensor INS may be directly disposed on the thin-film encapsulation layer TFE. In the present specification, when “configuration A is directly disposed on configuration B,” an adhesive layer is not disposed between the configuration A and the configuration B.

The base layer BL may include at least one plastic film. The base layer BL may be a flexible substrate, and may include a plastic substrate, a glass substrate, a metal substrate, an organic/inorganic composite material substrate, or the like. The display region DA and the non-display region NDA described above with reference to FIG. 1B may be identically defined in the base layer BL.

The circuit element layer DP-CL may include at least one insulating layer, and a circuit element. The insulating layer includes at least one inorganic layer, and at least one organic layer. The circuit element includes a signal line, a driver of a pixel, and the like.

The display element layer DP-OLED may include a partition wall and a light-emitting element. The light-emitting element may include an anode, an intermediate layer, and a cathode.

The thin-film encapsulation layer TFE may include a plurality of thin-films. Some of the thin-films may be disposed so as to improve an optical efficiency, and others of the thin-films may be disposed so as to protect organic light-emitting diodes.

The input sensor INS acquires coordinate information of an external input. The input sensor INS may have a multi-layered structure. The input sensor INS may include a single-layer or a multi-layered conductive layer. In addition, the input sensor INS may be a single-layer or a multi-layered insulating layer. The input sensor INS may detect an external input in a capacitive manner. However, the present disclosure is not limited thereto. For example, in an embodiment, the input sensor INS may detect an external input in an electromagnetic induction method or a pressure-detecting method. However, the input sensor INS may be omitted as needed or desired in another embodiment of the present disclosure.

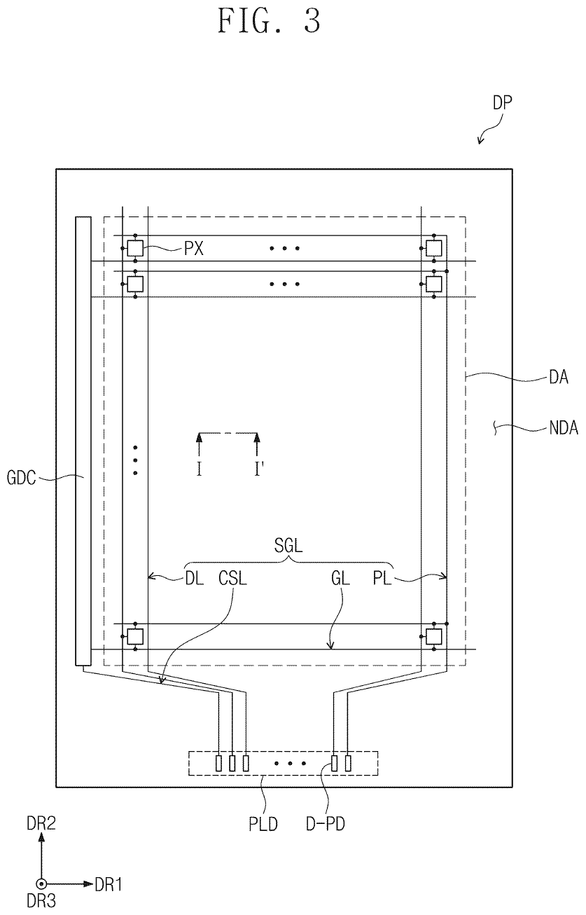

FIG. 3 is a plan view of a display panel according to an embodiment of the present disclosure.

Referring to FIG. 3, a display region DA and a non-display region NDA around the display region DA may be defined in the display panel DP. The display panel DP may include pixels PX, and signal lines SGL electrically connected to the pixels PX. The display panel DP may include a driving circuit GDC and a pad portion PLD. The display region DA and the non-display region NDA may be distinguished from each other based on whether or not the pixels PX are disposed. The pixels PX may be disposed in the display region DA. The driving circuit GDC and the pad portion PLD may be disposed in the non-display region NDA.

The pixels PX may be arranged along the first direction DR1 and the second direction DR2. The pixels PX may include a plurality of pixel rows extending in the first direction DR1 and arranged along the second direction DR2, and a plurality of pixel columns extending in the second direction DR2 and arranged along the first direction DR1.

The signal lines SGL may include gate lines GL, data lines DL, a power line PL, and a control signal line CSL. The gate lines GL may be connected to corresponding pixels of the pixels PX, and the data lines DL may be connected to corresponding pixels of the pixels PX, respectively. The power line PL may be electrically connected to the pixels PX. The control signal line CSL may be connected to the driving circuit GDC to supply control signals to the driving circuit GDC.

The driving circuit GDC may include a gate driver. The gate driver may generate gate signals, and may sequentially output the generated gate signals to the gate lines GL. The gate driver may further output another control signal to a pixel driver.

The pad portion PLD may be a portion to which a flexible circuit board is connected. The pad portion PLD may include pixel pads D-PD, and the pixel pads D-PD may be pads for connecting the flexible circuit board to the display panel DP. The pixel pads D-PD may be connected to corresponding signal lines of the signal lines SGL, respectively. The pixel pads D-PD may be connected to corresponding pixels PX, respectively, through the signal lines SGL. In addition, one pixel pad of the pixel pads D-PD may be connected to the driving circuit GDC.

In addition, the pad portion PLD may further include input pads. The input pads may be pads for connecting the flexible circuit board to the input sensor INS (e.g., see FIG. 2). However, the present disclosure is not limited thereto, and the input pads may be disposed in the input sensor INS (e.g., see FIG. 2) to connect the pixel pads D-PD to a separate circuit board. As another example, the input sensor INS (e.g., see FIG. 2) may be omitted as needed or desired, and the input pads may be omitted as needed or desired.

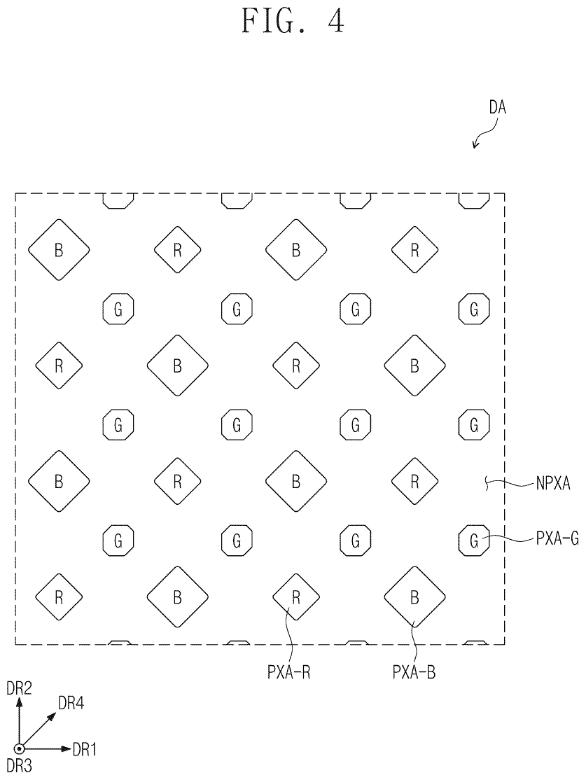

FIG. 4 is a partially enlarged plan view of the display region DA of the display panel DP according to an embodiment of the present disclosure. FIG. 4 illustrates a plane of the display module DM viewed on the display surface IS (e.g., see FIG. 1B) of the display module DM, and shows an arrangement of light-emitting regions PXA-R, PXA-G, and PXA-B.

Referring to FIG. 4, the display region DA may include first to third light-emitting regions PXA-R, PXA-G, and PXA-B, and a peripheral region NPXA surrounding (e.g., around peripheries of) the first to third light-emitting regions PXA-R, PXA-G, and PXA-B. The first to third light-emitting regions PXA-R, PXA-G, and PXA-B may correspond to regions from which light supplied from the light-emitting elements are emitted, respectively. The first to third light-emitting regions PXA-R, PXA-G, and PXA-B may be distinguished from one another by colors of the light emitted to the outside of the display module DM (e.g., see FIG. 2).

The first to third light-emitting regions PXA-R, PXA-G, and PXA-B may supply first to third color light, respectively, having different colors from each other. For example, the first color light may be red light, the second color light may be green light, and the third color light may be blue light. However, the present disclosure is not limited thereto, and the examples of the first to third color light are not limited to the aforementioned examples.

The first to third light-emitting regions PXA-R, PXA-G, and PXA-B may be defined as regions to which upper surfaces of the anodes are exposed by light-emitting openings described in more detail below, respectively. The peripheral region NPXA may define (e.g., may set) boundaries of the first to third light-emitting regions PXA-R, PXA-G, and PXA-B, and may prevent or substantially prevent color mixing between the first to third light-emitting regions PXA-R, PXA-G, and PXA-B.

The first to third light-emitting regions PXA-R, PXA-G, and PXA-B may each be provided in a plurality, and may each be repeatedly disposed in a suitable arrangement (e.g., a predetermined arrangement) form in the display region DA. For example, the first and third light-emitting regions PXA-R and PXA-B may be alternately arranged along the first direction DR1 to constitute ‘a first group’. The second light-emitting regions PXA-G may be arranged along the first direction DR1 to constitute ‘a second group’. ‘The first group’ and ‘the second group’ may each be provided in a plurality, and ‘the first groups’ and ‘the second groups’ may be alternately arranged along the second direction DR2.

One second light-emitting region PXA-G may be disposed to be spaced apart from one first light-emitting region PXA-R or one third light-emitting region PXA-B in a fourth direction DR4. The fourth direction DR4 may be defined as a direction between the first and second directions DR1 and DR2.

FIG. 4 illustrates an example arrangement form of the first to third light-emitting regions PXA-R, PXA-G, and PXA-B, but the present disclosure is not limited thereto, and the first to third light-emitting regions PXA-R, PXA-G, and PXA-B may be arranged in various suitable forms. In an embodiment, as illustrated in FIG. 4, the first to third light-emitting regions PXA-R, PXA-G, and PXA-B may have an RGBG arrangement form (e.g., a PENTILE® arrangement form, PENTILE® being a duly registered trademark of Samsung Display Co., Ltd.). As another example, the first to third light-emitting regions PXA-R, PXA-G, and PXA-B may have a stripe arrangement form, or a Diamond Pixel™ arrangement form.

The first to third light-emitting regions PXA-R, PXA-G, and PXA-B may have various suitable shapes on a plane (e.g., in a plan view). For example, the first to third light-emitting regions PXA-R, PXA-G, and PXA-B may have a suitable shape, such as a polygon, a circle, or an ellipse. FIG. 4 illustrates the first and third light-emitting regions PXA-R and PXA-B having a tetragonal shape (e.g., a rhombus shape), and the second light-emitting region PXA-G having an octagonal shape, as a representative example.

The first to third light-emitting regions PXA-R, PXA-G, and PXA-B may have the same or substantially the same shape as each other on a plane (e.g., in a plan view), or at least a portion thereof may have a different shape from the others. FIG. 4 illustrates the first and third light-emitting regions PXA-R and PXA-B having the same or substantially the same shape as each other, and the second light-emitting region PXA-G having a shape different from those of the first and third light-emitting regions PXA-R and PXA-B, as a representative example.

At least a portion of the first to third light-emitting regions PXA-R, PXA-G, and PXA-B may have a different area from the others on a plane (e.g., in a plan view). In an embodiment, the first light-emitting region PXA-R for emitting red light may have a greater area than that of the second light-emitting region PXA-G for emitting green light, and may have a smaller area than that of the third light-emitting region PXA-B for emitting blue light. However, the present disclosure is not limited thereto, and the relative size in the areas of the first to third light-emitting regions PXA-R, PXA-G, and PXA-G depending on the colors of light emitted thereby may be variously modified according to the design of the display module DM (e.g., see FIG. 2). In addition, the present disclosure is not limited thereto, and the first to third light-emitting regions PXA-R, PXA-G, and PXA-B may have the same or substantially the same area as each other on a plane (e.g., in a plan view).

The shapes, the areas, and the arrangements of the first to third light-emitting regions PXA-R, PXA-G, and PXA-B of the display module DM (e.g., see FIG. 2) according to the present disclosure may be variously designed according to the colors of light emitted thereby, or a size or a configuration of the display module DM, and thus, the present disclosure is not limited to those illustrated in FIG. 4.

FIG. 5 is a cross-sectional view of a display panel taken along the line I-I′ in FIG. 3 according to an embodiment of the present disclosure. FIG. 5 will be described in more detail hereinafter with reference to FIG. 2, and redundant description of the components denoted by the same reference numerals or symbols therebetween may not be repeated. A light-emitting region PXA in the display region DA (e.g., see FIG. 4) is illustrated as being enlarged in FIG. 5, and the light-emitting region PXA in FIG. 5 may correspond to any one of the first to third light-emitting regions PXA-R, PXA-G, and PXA-B in FIG. 4.

Referring to FIG. 5, a display panel DP may include a base layer BL, a circuit element layer DP-CL, a display element layer DP-OLED, and a thin-film encapsulation layer TFE.

The display panel DP may include a plurality of insulating layers, a semiconductor pattern, a conductive pattern, a signal line, and the like. The insulating layers, a semiconductor layer, and a conductive layer may be formed by coating, deposition, or the like. Thereafter, the insulating layers, the semiconductor layer, and the conductive layer may be selectively patterned by photolithography and etching. By using such methods, the semiconductor pattern, the conductive pattern, the signal line, and the like included in the circuit element layer DP-CL and the display element layer DP-OLED may be formed.

The circuit element layer DP-CL may be disposed on the base layer BL. The circuit element layer DP-CL may include a buffer layer BFL, a transistor TR1, a signal transmission region SCL, first to fifth insulating layers 10, 20, 30, 40, and 50, an electrode EE, and a plurality of connection electrodes CNE1 and CNE2.

The buffer layer BFL may be disposed on the base layer BL. The buffer layer BFL may improve a binding force between the base layer BL and the semiconductor pattern. The buffer layer BFL may include a silicon oxide layer and a silicon nitride layer. The silicon oxide layer and the silicon nitride layer may be alternately stacked.

The semiconductor pattern may be disposed on the buffer layer BFL. The semiconductor pattern may include polysilicon, but the present disclosure is not limited thereto, and the semiconductor pattern may include amorphous silicon or a metal oxide. Some semiconductor patterns are illustrated in FIG. 5 as a representative example, and the semiconductor pattern may be further disposed in the plurality of light-emitting regions PXA-R, PXA-G, and PXA-B (e.g., see FIG. 4). The semiconductor pattern may be arranged according to a suitable rule (e.g., a specific or predetermined rule) throughout the plurality of light-emitting regions PXA-R, PXA-G, and PXA-B. The semiconductor pattern may have an electric property that is different according to whether or not it is doped. The semiconductor pattern may include a first region having a greater doping concentration, and a second region having a smaller doping concentration. The first region may be doped with an N-type dopant or a P-type dopant. A P-type transistor may include the first region that is doped with the P-type dopant. An N-type transistor may include the first region that is doped with the N-type dopant.

The first region has a greater conductive property than that of the second region, and substantially serves as an electrode or a signal line. The second region may substantially correspond to an active (e.g., a channel) of a transistor. In other words, a portion of the semiconductor pattern may be the active of the transistor, another portion of the semiconductor may be a source or a drain, and another portion of the semiconductor may be a conductive region.

A source S, an active A, and a drain D of the transistor TR1 may be formed from the semiconductor pattern. The signal transmission region SCL formed from the semiconductor pattern is partially illustrated in FIG. 5. Although not shown separately, the signal transmission region SCL may be connected to the drain D of the transistor TR1 on a plane (e.g., in a plan view).

The first to fifth insulating layers 10, 20, 30, 40, and 50 may be disposed on the buffer layer BFL. The first to fifth insulating layers 10, 20, 30, 40, and 50 may be an inorganic layer or an organic layer.

The first insulating layer 10 may be disposed on the buffer layer BFL. The first insulating layer 10 may cover the source S, the active A, and the drain D of the transistor TR1, and the signal transmission region SCL disposed on the buffer layer BFL. A gate G of the transistor TR1 may be disposed on the first insulating layer 10. The second insulating layer 20 may be disposed on the first insulating layer 10 to cover the gate G. The electrode EE may be disposed on the second insulating layer 20. The third insulating layer 30 may be disposed on the second insulating layer 20 to cover the electrode EE.

The first connection electrode CNE1 may be disposed on the third insulating layer 30. The first connection electrode CNE1 may be connected to the signal transmission region SCL through a contact hole CNT-1 penetrating the first to third insulating layers 10, 20, and 30. The fourth insulating layer 40 may be disposed on the third insulating layer 30 to cover the first connection electrode CNE1. The fourth insulating layer 40 may be an organic layer.

The second connection electrode CNE2 may be disposed on the fourth insulating layer 40. The second connection electrode CNE2 may be connected to the first connection electrode CNE1 through a contact hole CNT-2 penetrating the fourth insulating layer 40. The fifth insulating layer 50 may be disposed on the fourth insulating layer 40 to cover the second connection electrode CNE2. The fifth insulating layer 50 may be an organic layer.

The display element layer DP-OLED may be disposed on the circuit element layer DP-CL. The display element layer DP-OLED may include a light-emitting element ED, a lower sacrificial pattern SP1, a capping pattern CP, a pixel-defining film PDL, a partition wall PW, an upper sacrificial pattern SP2, and dummy patterns DMP. In the present disclosure, the upper sacrificial pattern SP2 may be referred to as a sacrificial pattern SP2.

The light-emitting element ED may include an anode AE (e.g., a first electrode), a light-emitting pattern EP, and a cathode CE (e.g., a second electrode). At least a portion of the light-emitting element ED may be disposed in a partition wall opening OP-P.

The anode AE may be disposed on the fifth insulating layer 50 of the circuit element layer DP-CL. The anode AE may be a transmissive electrode, a semi-transmissive electrode, or a reflective electrode. The anode AE may be connected to the second connection electrode CNE2 through a contact hole CNT-3 penetrating the fifth insulating layer 50. Accordingly, the anode AE may be electrically connected to the signal transmission region SCL through the first and second connection electrodes CNE1 and CNE2 to be electrically connected to a corresponding circuit element. The anode AE may include a single-layer or multi-layered structure. The anode AE may include a plurality of layers including ITO, or silver (Ag). For example, the anode AE may include a layer (hereinafter, a lower ITO layer) including ITO, a layer (hereinafter, a silver (Ag) layer) including silver (Ag) disposed on the lower ITO layer, and a layer (hereinafter, an upper ITO layer) including ITO disposed on the silver (Ag) layer.

The lower sacrificial pattern SP1 may be disposed between the anode AE and the pixel-defining film PDL. The lower sacrificial pattern SP1 may have a lower sacrificial opening OP-S1 partially exposing an upper surface of the anode AE. The lower sacrificial opening OP-S1 may overlap with a light-emitting opening OP-E to be described in more detail below.

The lower sacrificial pattern SP1 may include a transparent conductive oxide. For example, the lower sacrificial pattern SP1 may include indium-tin oxide (ITO), indium-zinc oxide (IZO), zinc oxide, indium oxide, indium-gallium oxide, indium-gallium-zinc oxide (IGZO), aluminum-zinc oxide, or zinc-indium-tin oxide (ZITO). In an embodiment, the lower sacrificial pattern SP1 may include (e.g., may be) zinc-indium-tin oxide (ZITO) in which tin (Sn) of about 3 at % to about 14 at % is doped. The lower sacrificial pattern SP1 may have a thickness of about 100 Å to about 250 Å.

The pixel-defining film PDL may be disposed on the fifth insulating layer 50 of the circuit element layer DP-CL. The pixel-defining film PDL may have the light-emitting opening OP-E. The light-emitting opening OP-E may correspond to the anode AE, and the pixel-defining film PDL may at least partially expose the anode AE through the light-emitting opening OP-E.

In addition, the light-emitting opening OP-E may correspond to the lower sacrificial opening OP-S1 of the lower sacrificial pattern SP1. According to the present embodiment, the upper surface of the anode AE may be spaced apart from the pixel-defining film PDL on a cross-section with the lower sacrificial pattern SP1 therebetween. Accordingly, the anode AE may be protected from being damaged in a process of forming the light-emitting opening OP-E.

On a plane (e.g., in a plan view), the light-emitting opening OP-E may have a smaller area than that of the lower sacrificial opening OP-S1. In other words, an inner side surface of the pixel-defining film PDL having the light-emitting opening OP-E may be more adjacent to the center of the anode AE than an inner side surface of the lower sacrificial pattern SP1 having the lower sacrificial opening OP-S1. However, the present disclosure is not limited thereto, and the inner side surface of the lower sacrificial pattern SP1 having the lower sacrificial opening OP-S1 may be aligned or substantially aligned with the inner side surface of the pixel-defining film PDL having the light-emitting opening OP-E. In this case, the light-emitting region PXA may be a region of the anode AE exposed from the lower sacrificial opening OP-S1 corresponding thereto.

The pixel-defining film PDL may include a first pixel-defining film PDL1 and a second pixel-defining film PDL2. The light-emitting opening OP-E may include a first pixel opening OP-PDL1 and a second pixel opening OP-PDL2.

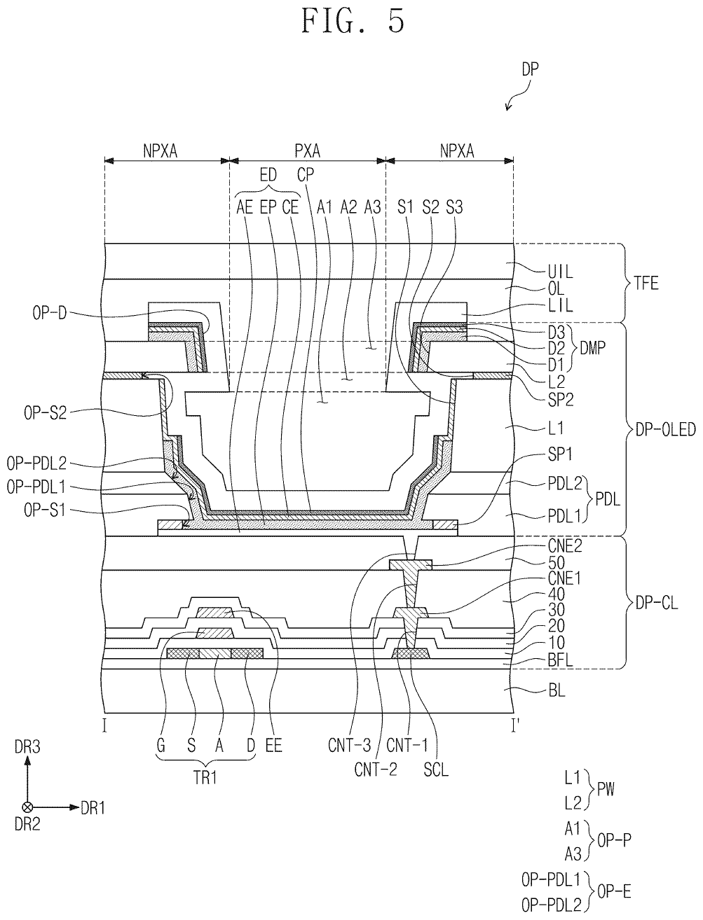

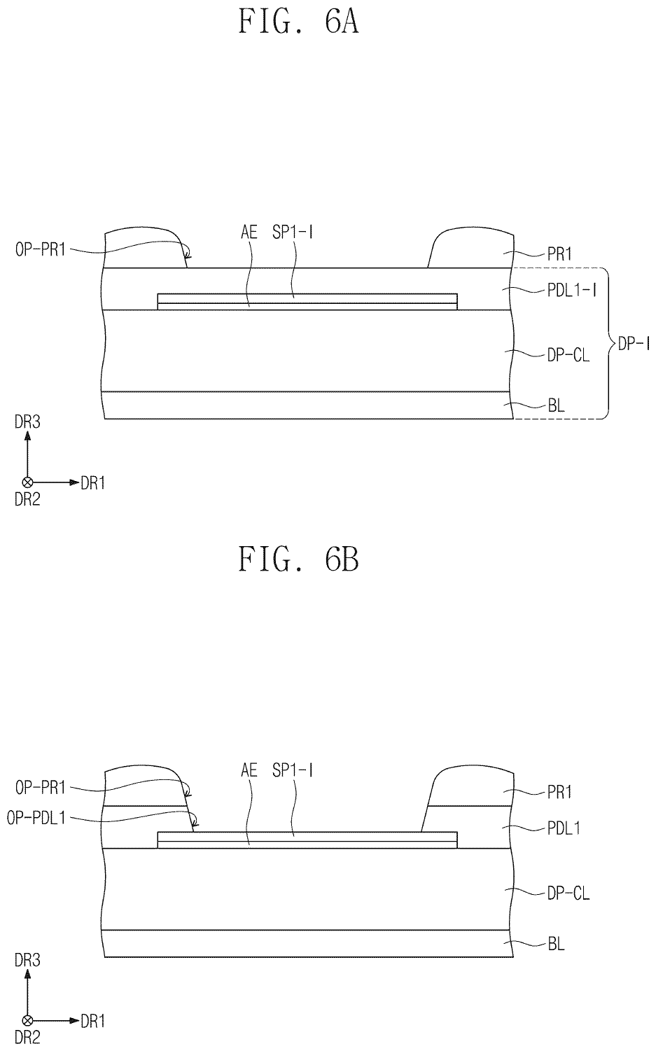

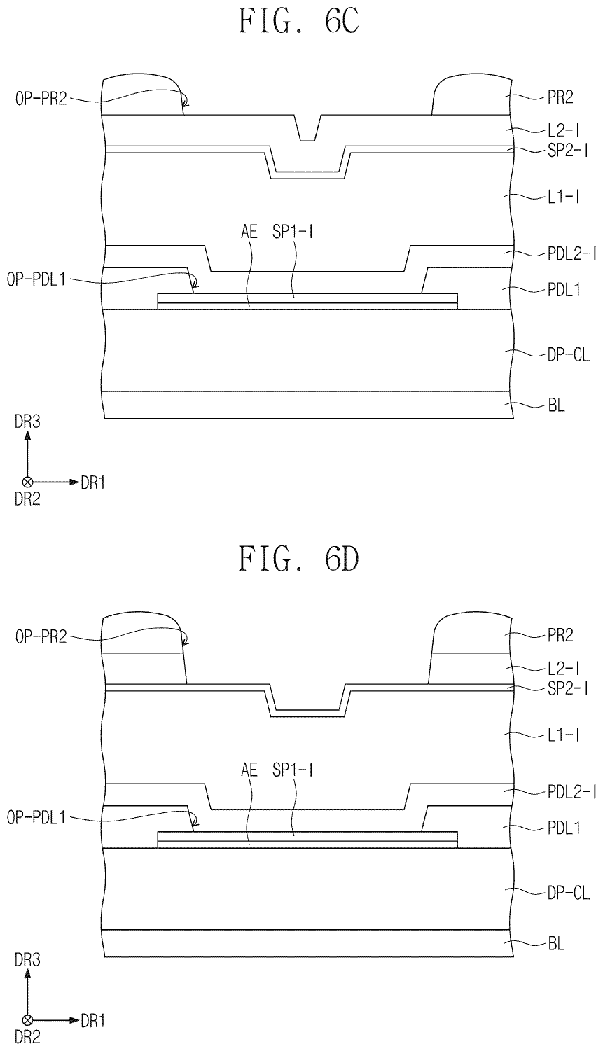

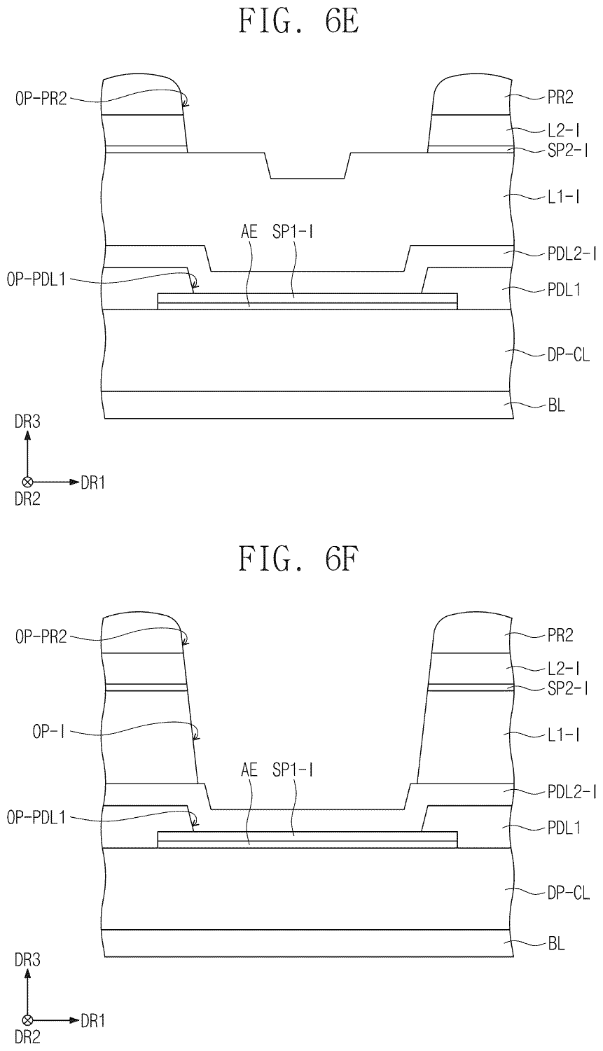

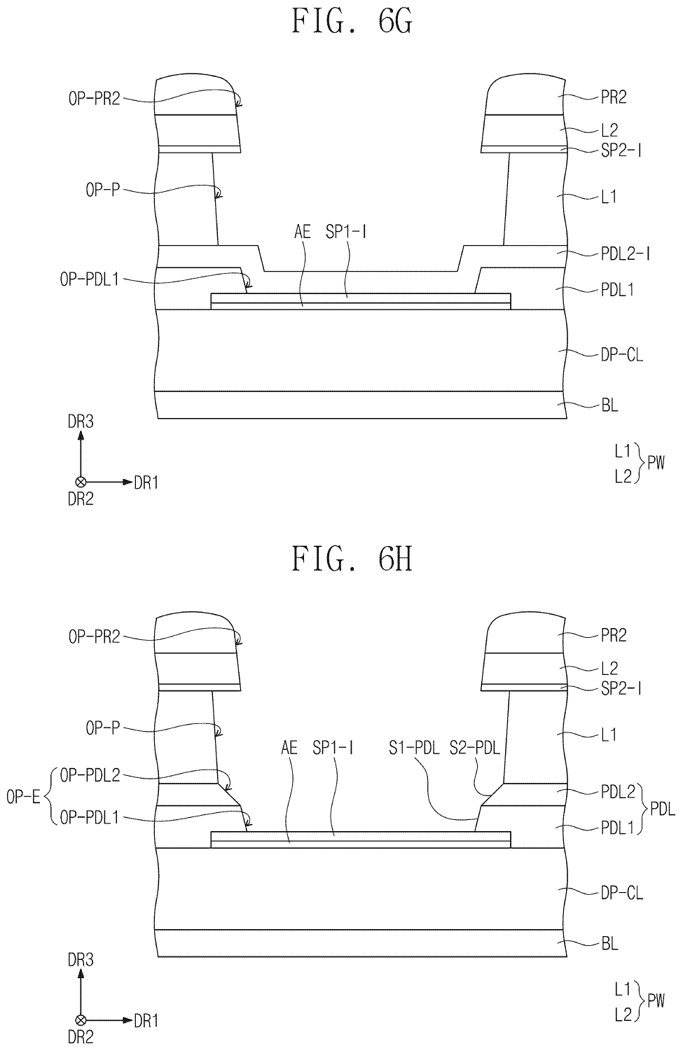

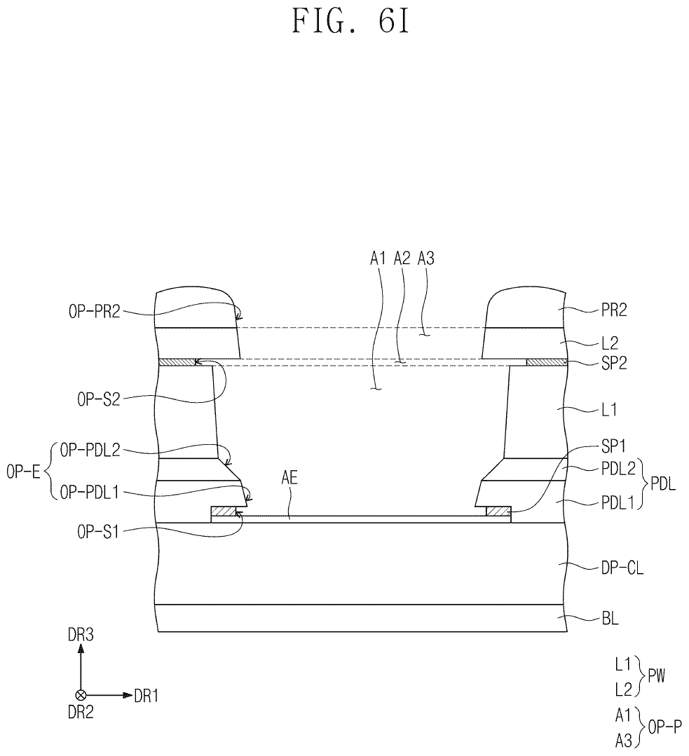

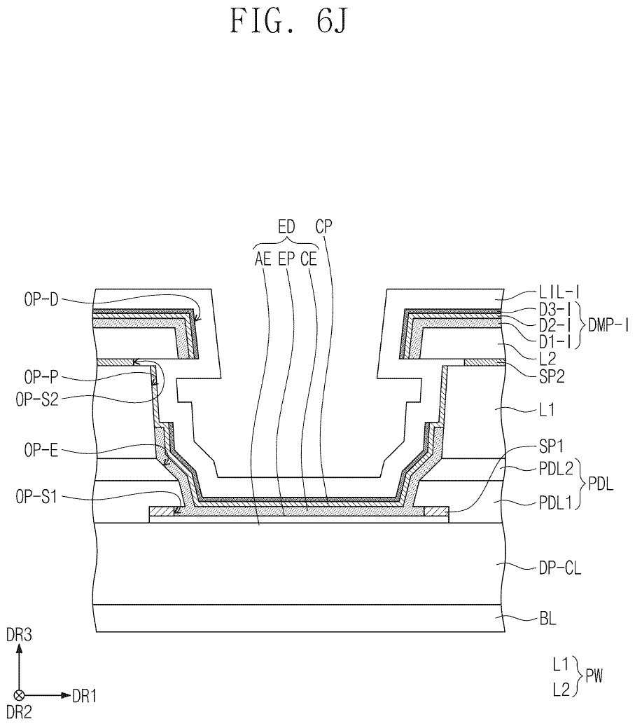

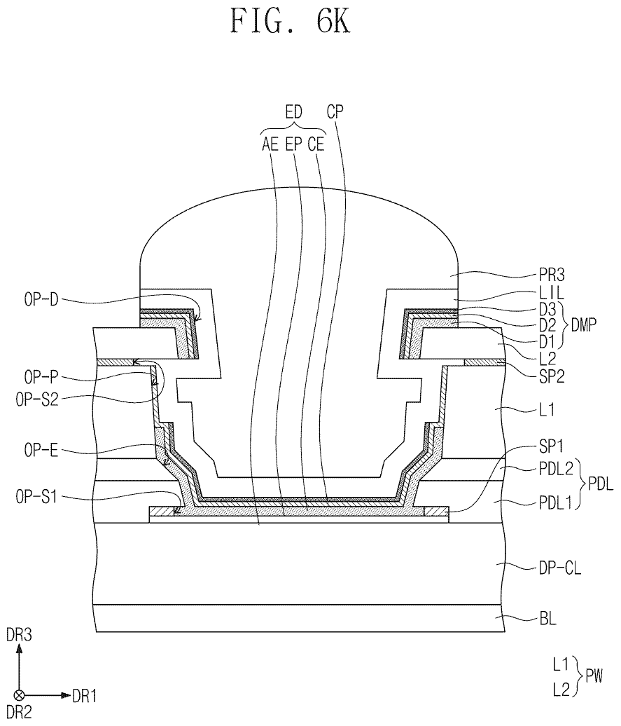

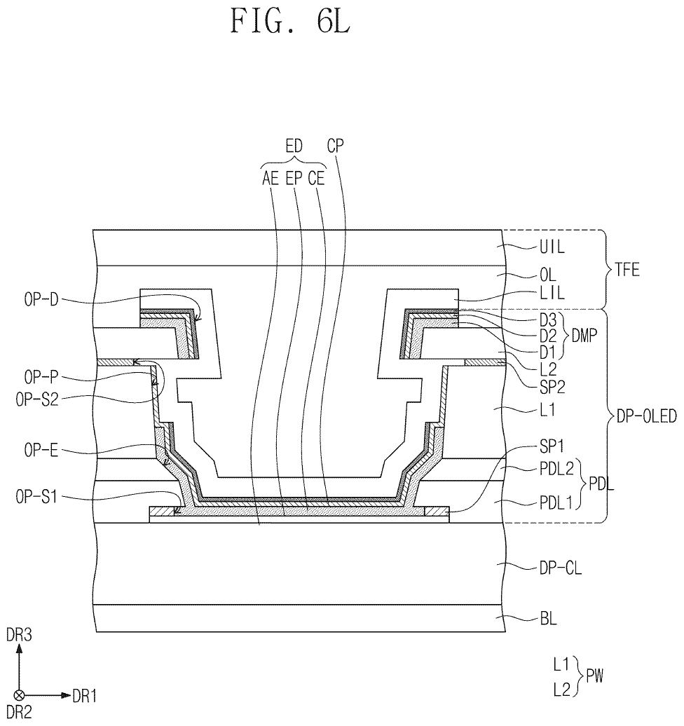

The first pixel-defining film PDL1 may be disposed on the circuit element layer DP-CL, and may include a first inner side surface S1-PDL (e.g., see FIG. 6H) defining the first pixel opening OP-PDL1 of the light-emitting opening OP-E. The second pixel-defining film PDL2 may be disposed on the first pixel-defining film PDL1, and may include a second inner side surface S2-PDL (e.g., see FIG. 6H) defining the second pixel opening OP-PDL2 of the light-emitting opening OP-E. A width of the first pixel opening OP-PDL1 in the first direction DR1 may be equal to or smaller than a width of the second pixel opening OP-PDL2 in the first direction DR1. However, the present disclosure is not limited thereto.

The first pixel-defining film PDL1 and the second pixel-defining film PDL2 may include an inorganic insulating material. For example, the first pixel-defining film PDL1 and the second pixel-defining film PDL2 may include silicon nitride (SiNx). The first pixel-defining film PDL1 and the second pixel-defining film PDL2 may be disposed between the anode AE and the partition wall PW to block the anode AE and the partition wall PW from being electrically connected to each other. In addition, the second pixel-defining film PDL2 may serve to protect the anode AE and the lower sacrificial pattern SP1 in a process of forming the light-emitting opening OP-E and the lower sacrificial opening OP-S1. This will be described in more detail below.

The light-emitting pattern EP may be disposed on the anode AE. The light-emitting pattern EP may include a light-emitting layer including a light-emitting material. The light-emitting pattern EP may further include a hole injection layer (HIL) and a hole transport layer (HTL) disposed between the anode AE and the light-emitting layer, and may further include an electron transport layer (ETL) and an electron injection layer (EIL) disposed on the light-emitting layer. The light-emitting pattern EP may be referred to as ‘an organic layer’ or ‘an intermediate layer’.

The light-emitting pattern EP may be patterned by a tip portion defined in the partition wall PW. The light-emitting pattern EP may be disposed in an inner side of the lower sacrificial opening OP-S1, the light-emitting opening OP-E, and the partition wall opening OP-P. The light-emitting pattern EP may partially cover an upper surface of the pixel-defining film PDL exposed from the partition wall opening OP-P.

The cathode CE may be disposed on the light-emitting pattern EP. The cathode CE may be patterned by the tip portion defined in the partition wall PW. At least a portion of the cathode CE may be disposed on the partition wall opening OP-P, and may be in contact with the partition wall PW in the partition wall opening OP-P. The cathode CE may be spaced apart from the upper sacrificial pattern SP2 to be described in more detail below.

The cathode CE may have a conductive property. The cathode CE may be formed of various suitable materials, such as a metal, a transparent conductive oxide (TCO), or a conductive polymeric material, as long as it has a conductive property. For example, the cathode CE may include silver (Ag), magnesium (Mg), lead (Pb), copper (Cu), or a suitable compound thereof.

The capping pattern CP may be disposed in the partition wall opening OP-P, and may be disposed on the cathode CE. The capping pattern CP may be patterned by the tip portion formed in the partition wall PW. FIG. 5 illustrates that the capping pattern CP is not in contact with a first side surface S1 of a first partition wall layer L1, but the present disclosure is not limited thereto. For example, the capping pattern CP may be formed so as to be in contact with the first side surface S1 of the first partition wall layer L1. According to another embodiment of the present disclosure, the capping pattern CP may be omitted as needed or desired.

The partition wall PW may be disposed on the pixel-defining film PDL. The partition wall PW may have the partition wall opening OP-P. The partition wall opening OP-P may correspond to the light-emitting opening OP-E, and may at least partially expose the anode AE. The partition wall PW may have an undercut shape on a cross-section. The partition wall PW may include multiple layers that are sequentially stacked, and at least one layer of the multiple layers may be recessed more than the other layers.

The partition wall PW may include the first partition wall layer L1 and a second partition wall layer L2. The first partition wall layer L1 may be disposed on the pixel-defining film PDL, and the second partition wall layer L2 may be disposed on the first partition wall layer L1. As illustrated in FIG. 5, the first partition wall layer L1 may have a greater thickness than that of the second partition wall layer L2, but the present disclosure is not limited thereto.

The first partition wall layer L1 may be relatively more recessed than the second partition wall layer L2 with respect to the light-emitting region PXA. The first partition wall layer L1 may have an undercut shape with respect to the second partition wall layer L2. A portion of the second partition wall layer L2 protruding from the first partition wall layer L1 toward the light-emitting region PXA may be defined as the tip portion of the partition wall PW.

The first partition wall layer L1 and the second partition wall layer L2 may each include a conductive material. For example, the conductive material may include a metal, a transparent conductive oxide (TCO), or a suitable combination thereof. For example, the metal may include gold (Au), silver (Ag), aluminum (Al), magnesium (Mg), lithium (Li), molybdenum (Mo), titanium (Ti), copper (Cu), or a suitable alloy thereof. The transparent conductive oxide (TCO) may include indium-tin oxide (ITO), indium-zinc oxide (IZO), zinc oxide, indium oxide, indium-gallium oxide, indium-gallium-zinc oxide (IGZO), or aluminum-zinc oxide.

The partition wall PW may receive a second driving voltage ELVSS, and accordingly, the cathode CE may be electrically connected to the partition wall PW to receive the second driving voltage ELVSS.

The upper sacrificial pattern SP2 may be disposed between the first partition wall layer L1 and the second partition wall layer L2 on a cross-section. The upper sacrificial pattern SP2 may include a transparent conductive oxide. For example, the upper sacrificial pattern SP2 may include indium-tin oxide (ITO), indium-zinc oxide (IZO), zinc oxide, indium oxide, indium-gallium oxide, indium-gallium-zinc oxide (IGZO), aluminum-zinc oxide, or zinc-indium-tin oxide (ZITO). In an embodiment, the upper sacrificial pattern SP2 may include (e.g., may be) the zinc-indium-tin oxide (ZITO) doped with tin (Sn) of about 15 at % to about 22 at %. The upper sacrificial pattern SP2 may have a thickness of about 250 Å to 1000 Å.

The upper sacrificial pattern SP2 may have an upper sacrificial opening OP-S2 overlapping with the partition wall opening OP-P. The upper sacrificial opening OP-S2 may be referred to as a sacrificial opening OP-S2. The upper sacrificial pattern SP2 may be relatively more recessed than the partition wall PW with respect to the light-emitting region PXA. The upper sacrificial pattern SP2 may have an undercut shape with respect to the partition wall PW. For example, the upper sacrificial pattern SP2 may have the undercut shape with respect to the first partition wall layer L1 and the second partition wall layer L2.

According to one or more embodiments of the present disclosure, because the upper sacrificial pattern SP2 is formed between the first partition wall layer L1 and the second partition wall layer L2, a path through which foreign matters introduced from a side surface of an inorganic lower encapsulation pattern LIL can pass may extend. In addition, because the upper sacrificial pattern SP2 has the undercut shape with respect to the first partition wall layer L1 and the second partition wall layer L2, the cathode CE may be spaced apart from the upper sacrificial pattern SP2. Accordingly, the upper sacrificial pattern SP2 including the transparent conductive oxide may be directly in contact with the inorganic lower encapsulation pattern LIL. Because a binding force between the inorganic lower encapsulation pattern LIL and the partition wall PW increases, a pixel defect (e.g., a dark point, a pixel shrinkage, or the like) may be reduced or removed.

The partition wall opening OP-P and the upper sacrificial opening OP-S2 may include a first region A1, a second region A2, and a third region A3. The partition wall opening OP-P may include the first region A1 and the third region A3, and the upper sacrificial opening OP-S2 may include the second region A2. The first to third regions A1, A2, and A3 may be integrally formed with each other in a thickness direction (e.g., the third direction DR3) of the base layer BL. A width of the second region A2 in the first direction DR1 may be greater than a width of the first region A1 in the first direction DR1 and a width of the third region A3 in the first direction DR1.

The first partition wall layer L1 may include a first side surface S1 defining the first region A1. The upper sacrificial pattern SP2 may include a second side surface S2 defining the second region A2. The second partition wall layer L2 may include a third side surface S3 defining the third region A3. The second side surface S2 of the upper sacrificial pattern SP2 may be recessed, in a direction getting farther from the partition wall opening OP-P, more than that of the first side surface S1 of the first partition wall layer L1 and the third side surface S3 of the second partition wall layer L2. On a plane (e.g., in a plan view), the second side surface S2 of the upper sacrificial pattern SP2 may overlap with the first partition wall layer L1 and the second partition wall layer L2.

The dummy patterns DMP may be disposed on the partition wall PW. The dummy patterns DMP may include a first dummy pattern D1, a second dummy pattern D2, and a third dummy pattern D3. The first to third dummy patterns D1, D2, and D3 may sequentially stacked on an upper surface of the second partition wall layer L2 of the partition wall PW along the third direction DR3.

The first dummy pattern D1 may include an organic material. For example, the first dummy pattern D1 may include the same material as that of the light-emitting pattern EP. The first dummy pattern D1 may be concurrently or substantially simultaneously formed with the light-emitting pattern EP through one process, and may be separately formed with the light-emitting pattern EP due to the undercut shape of the partition wall PW.

The second dummy pattern D2 may include a conductive material. For example, the second dummy pattern D2 may include the same material as that of the cathode CE. The second dummy pattern D2 may be concurrently or substantially simultaneously formed with the cathode CE through one process, and may be separately formed with the cathode CE due to the undercut shape of the partition wall PW.

The third dummy pattern D3 may include a conductive material. For example, the third dummy pattern D3 may include the same material as that of the capping pattern CP. The third dummy pattern D3 may be concurrently or substantially simultaneously formed with the capping pattern CP through one process, and may be separately formed with the capping pattern CP due to the undercut shape of the partition wall PW.

The dummy patterns DMP may have a dummy opening OP-D. The dummy opening OP-D may correspond to the light-emitting opening OP-E. On a plane (e.g., in a plan view), the first to third dummy patterns D1, D2, and D3 may each have a closed line shape surrounding (e.g., around a periphery of) the light-emitting region PXA.

FIG. 5 illustrates that the first to third dummy patterns D1, D2, and D3 cover the third side surface S3 of the second partition wall layer L2, but the present disclosure is not limited thereto. For example, inner side surfaces of the first to third dummy patterns D1, D2, and D3 may be formed to be aligned or substantially aligned with the third side surface S3 of the second partition wall layer L2. In this case, the dummy opening OP-D may include a first region defined by an inner side surface of the first dummy pattern D1, a second region defined by an inner side surface of the second dummy pattern D2, and a third region defined by an inner side surface of the third dummy pattern D3.

The thin-film encapsulation layer TFE may be disposed on the display element layer DP-OLED. The thin-film encapsulation layer TFE may include the inorganic lower encapsulation pattern LIL, the organic encapsulation film OL, and the inorganic upper encapsulation film UIL.

The inorganic lower encapsulation pattern LIL may be disposed corresponding to the light-emitting opening OP-E. For example, a portion of the inorganic lower encapsulation pattern LIL may be disposed in the partition wall opening OP-P, and another portion of the inorganic lower encapsulation pattern LIL may be disposed on the partition wall PW. The portion of the inorganic lower encapsulation pattern LIL disposed in the partition wall opening OP-P may be disposed on the cathode CE and/or the capping pattern CP to cover the cathode CE.

The organic encapsulation film OL may cover the inorganic lower encapsulation pattern LIL, and may supply a flat or substantially flat upper surface. The inorganic upper encapsulation film UIL may be disposed on the organic encapsulation film OL.

The inorganic lower encapsulation pattern LIL and the inorganic upper encapsulation film UIL may protect the display element layer DP-OLED from moisture/oxygen, and the organic encapsulation film OL may protect the display element layer DP-OLED from foreign matters such as dust particles.

FIGS. 6A through 6L are cross-sectional views illustrating some operations of a method for manufacturing a display panel according to an embodiment of the present disclosure. In FIGS. 6A through 6L, the same/similar components and configurations are denoted using the same/similar reference numerals or symbols as those described above with reference to FIGS. 1 through 5, and thus, redundant description thereof may not be repeated.

The method for manufacturing a display panel according to one or more embodiments of the present disclosure may include providing a preliminary display panel including a base layer, and an anode, a lower sacrificial layer, and a first preliminary pixel-defining film disposed on the base layer; forming a first pixel-defining film by etching the first preliminary pixel-defining film; sequentially depositing, on the first pixel-defining film, a second preliminary pixel-defining film, a first preliminary partition wall layer, a sacrificial layer, and a second preliminary partition wall layer; and forming a second pixel-defining film, a partition wall, and a sacrificial pattern by etching the second preliminary pixel-defining film, the first preliminary partition wall layer, the sacrificial layer, and the second preliminary partition wall layer.

Referring to FIG. 6A, the method for manufacturing a display panel according to one or more embodiments of the present disclosure may include an operation of providing a preliminary display panel DP-I.

The preliminary display panel DP-I provided in an embodiment of the present disclosure may include a base layer BL, a circuit element layer DP-CL, an anode AE, a lower sacrificial pattern SP1-I, and a first preliminary pixel-defining film PDL1-I.

The circuit element layer DP-CL may be formed through a process, of manufacturing a circuit element, of forming a semiconductor pattern, a conductive pattern, a signal line, and the like, by forming an insulating layer, a semiconductor layer, and a conductive layer by coating, deposition, or the like, and selectively patterning the insulating layer, the semiconductor layer, and the conductive layer by photolithography and etching.

The anode AE and the lower sacrificial pattern SP1-I may be formed by the same patterning process. The lower sacrificial pattern SP1-I may include a transparent conductive oxide. For example, the lower sacrificial pattern SP1-I may include indium-tin oxide (ITO), indium-zinc oxide (IZO), zinc oxide, indium oxide, indium-gallium oxide, indium-gallium-zinc oxide (IGZO), aluminum-zinc oxide, or zinc-indium-tin oxide (ZITO). In an embodiment, the lower sacrificial pattern SP1-I may include (e.g., may be) zinc-indium-tin oxide (ZITO) doped with tin (Sn) of about 14 at %.

The first preliminary pixel-defining film PDL1-I may be formed on the base layer BL. The first preliminary pixel-defining film PDL1-I may cover all of the anode AE and the lower sacrificial pattern SP1-1. The first preliminary pixel-defining film PDL1-I may include an inorganic material. For example, the first preliminary pixel-defining film PDL1-I may include silicon nitride (SiNx).

The method for manufacturing a display panel according to one or more embodiments of the present disclosure may include an operation of forming a first photoresist layer PR1 on the first preliminary pixel-defining film PDL1-1. The first photoresist layer PR1 may be formed by patterning a preliminary photoresist layer by using a photomask after forming the preliminary photoresist layer on the first preliminary pixel-defining film PDL1-I. A first photo opening OP-PR1 overlapping with the anode AE may be formed in the first photoresist layer PR1 through the patterning process.

Referring to FIG. 6B, the method for manufacturing a display panel according to one or more embodiments of the present disclosure may include an operation of forming a first pixel-defining film PDL1 by etching the first preliminary pixel-defining film PDL1-I (e.g., see FIG. 6A). In the operation of forming the first pixel-defining film PDL1, the first preliminary pixel-defining film PDL1-I may be dry-etched by using the first photoresist layer PR1 as a mask. A portion of the first preliminary pixel-defining film PDL1-I not overlapping with the first photoresist layer PR1 may be etched to be removed, and the other remaining portion of the first preliminary pixel-defining film PDL1-I that is not etched and left over may be the first pixel-defining film PDL1. A first pixel opening OP-PDL1 of the first pixel-defining film PDL1 may be formed by the portion that is etched and removed. The first pixel opening OP-PDL1 may overlap with the first photo opening OP-PR1 of the first photoresist layer PR1.

Referring to FIG. 6C, the method for manufacturing a display panel according to one or more embodiments of the present disclosure may include an operation of sequentially depositing, on the first pixel-defining film PDL1, a second preliminary pixel-defining film PDL2-1, a first preliminary partition wall layer L1-1, an upper sacrificial layer SP2-I, and a second preliminary partition wall layer L2-I, after removing the first photoresist layer PR1 (e.g., see FIG. 6B). In the present disclosure, the upper sacrificial layer SP2-I may be referred to as a sacrificial layer SP2-1.

The second preliminary pixel-defining film PDL2-I may be formed on the first pixel-defining film PDL1. The second preliminary pixel-defining film PDL2-I may include an inorganic material. For example, the second preliminary pixel-defining film PDL2-I may include silicon nitride (SiNx).

The first preliminary partition wall layer L1-I may be formed by a process of depositing a conductive material on the second preliminary pixel-defining film PDL2-1. The first preliminary partition wall layer L1-I may include the conductive material. For example, the conductive material may include a metal, a transparent conductive oxide (TCO), or a suitable combination thereof. For example, the metal may include gold (Au), silver (Ag), aluminum (Al), magnesium (Mg), lithium (Li), molybdenum (Mo), titanium (Ti), copper (Cu), or a suitable alloy thereof. The transparent conductive oxide may include indium-tin oxide (ITO), indium-zinc oxide (IZO), zinc oxide, indium oxide, indium-gallium oxide, indium-gallium-zinc oxide (IGZO), or aluminum-zinc oxide.

The upper sacrificial layer SP2-I (e.g., the sacrificial layer) may be formed in a process of depositing a conductive material on the first preliminary partition wall layer L1-1. The upper sacrificial layer SP2-I may include a transparent conductive oxide. For example, the upper sacrificial layer SP2-I may include indium-tin oxide (ITO), indium-zinc oxide (IZO), zinc oxide, indium oxide, indium-gallium oxide, indium-gallium-zinc oxide (IGZO), aluminum-zinc oxide, or zinc-indium-tin oxide (ZITO). In an embodiment, the upper sacrificial layer SP2-I may include (e.g., may be) zinc-indium-tin oxide (ZITO) doped with tin (Sn) of about 22 at %.

The second preliminary partition wall layer L2-I may be formed in a process of depositing a conductive material on the upper sacrificial layer SP2-1. The second preliminary partition wall layer L2-I may include the conductive material. For example, the conductive material may include a metal, a transparent conductive oxide (TCO), or a suitable combination thereof. For example, the metal may include gold (Au), silver (Ag), aluminum (Al), magnesium (Mg), lithium (Li), molybdenum (Mo), titanium (Ti), copper (Cu), or a suitable alloy thereof. The transparent conductive oxide may include indium-tin oxide (ITO), indium-zinc oxide (IZO), zinc oxide, indium oxide, indium-gallium oxide, indium-gallium-zinc oxide (IGZO), or aluminum-zinc oxide.

The method for manufacturing a display panel according to one or more embodiments of the present disclosure may include an operation of forming a second photoresist layer PR2 on the second preliminary partition wall layer L2-1. The second photoresist layer PR2 may be formed by patterning a preliminary photoresist layer by using a photomask, after forming the preliminary photoresist layer on the second preliminary partition wall layer L2-I. A second photo opening OP-PR2 overlapping with the anode AE may be formed in the second photoresist layer PR2 through a patterning process.

Referring to FIGS. 6D through 6I, the method for manufacturing a display panel according to one or more embodiments of the present disclosure may include an operation of forming a second pixel-defining film PDL2, a partition wall PW, and a upper sacrificial pattern SP2 by etching the second preliminary pixel-defining film PDL2-1, the first preliminary partition wall layer L1-1, the upper sacrificial layer SP2-I, and the second preliminary partition wall layer L2-I (e.g., see FIG. 6C). The operation of forming the second pixel-defining film PDL2, the partition wall PW, and the upper sacrificial pattern SP2 may include an operation of etching the second preliminary partition wall layer L2-I, an operation of etching the upper sacrificial layer SP2-I, an operation of etching the first preliminary partition wall layer L1-I, an operation of forming the partition wall PW having the partition wall opening OP-P by etching the first and second preliminary partition wall layers L1-I and L2-1, an operation of forming the second pixel-defining film PDL2 by etching the second preliminary pixel-defining film PDL2-I, and an operation of forming the upper sacrificial pattern SP2 by etching the upper sacrificial layer SP2-I.

In more detail, as illustrated in FIG. 6D, the operation of forming the second pixel-defining film PDL2 (e.g., see FIG. 6I), the partition wall PW, and the upper sacrificial pattern SP2 may include the operation of etching the second preliminary partition wall layer L2-I (e.g., see FIG. 6C). In the operation of etching the second preliminary partition wall layer L2-1, the second preliminary partition wall layer L2-I may be dry-etched by using the second photoresist layer PR2 as a mask. A portion, of the second preliminary partition wall layer L2-I not overlapping with the second photoresist layer PR2 may be etched to be removed. In other words, the portion of the second preliminary partition wall layer L2-I overlapping with the second photo opening OP-PR2 may be etched and removed.

As illustrated in FIG. 6E, the operation of forming the second pixel-defining film PDL2 (e.g., see FIG. 6I), the partition wall PW, and the upper sacrificial pattern SP2 may include the operation of etching the upper sacrificial layer SP2-I (e.g., see FIG. 6D). The operation of etching the upper sacrificial layer SP2-I may be wet-etching the upper sacrificial layer SP2-I by using the second photoresist layer PR2 as a mask. A portion of the upper sacrificial layer SP2-I not overlapping with the second photoresist layer PR2 may be etched to be removed. In other words, the portion of the upper sacrificial layer SP2-I overlapping with the second photo opening OP-PR2 may be etched and removed.

As illustrated in FIG. 6F, the operation of forming the second pixel-defining film PDL2 (e.g., see FIG. 6I), the partition wall PW, and the upper sacrificial pattern SP2 may include the operation of etching the first preliminary partition wall layer L1-1. In the operation of etching the first preliminary partition wall layer L1-1, the first preliminary partition wall layer L1-I may be dry-etched by using the second photoresist layer PR2 as a mask. A portion of the first preliminary partition wall layer L1-I not overlapping with the second photoresist layer PR2 may be etched to be removed. In other words, the portion of the first preliminary partition wall layer L1-I overlapping with the second photo opening OP-PR2 may be etched and removed. An inner side surface of the first preliminary partition wall layer L1-I, an inner side surface of the upper sacrificial layer SP2-I, and an inner side surface of the second preliminary partition wall layer L2-1, which have a preliminary opening OP-I, may be aligned or substantially aligned with each other.

As illustrated in FIG. 6G, the operation of forming the second pixel-defining film PDL2 (e.g., see FIG. 6I), the partition wall PW, and the upper sacrificial pattern SP2 may include the operation of forming the partition wall PW having the partition wall opening OP-P by etching the first preliminary partition wall layer L1-I (e.g., see FIG. 6F) and the second preliminary partition wall layer L2-1. In the operation of forming the partition wall PW having the partition wall opening OP-P by etching the first preliminary partition wall layer L1-I and the second preliminary partition wall layer L2-1, the first preliminary partition wall layer L1-I and the second preliminary partition wall layer L2-1 may be wet-etched by using the second photoresist layer PR2 as a mask. The first partition wall layer L1 and the second partition wall layer L2 formed by etching may be defined as the partition wall PW.

During the above process, the upper sacrificial layer SP2-I may be also partially etched. FIG. 6G illustrates that the upper sacrificial layer SP2-I is partially etched so that a side surface of the second preliminary partition wall layer L2-I and a side surface of the upper sacrificial layer SP2-I are aligned with each other, but the present disclosure is not limited thereto. For example, the side surface of the upper sacrificial layer SP2-I may be formed to be more recessed inward than the side surface of the second preliminary partition wall layer L2-1.

In an embodiment, when an etching selectivity of the first preliminary partition wall layer L1-I and the second preliminary partition wall layer L2-I is great, the wet-etching process may be performed. Accordingly, the second partition wall layer L2 may have a shape in which the second partition wall layer L2 protrudes more toward the partition wall opening OP-P than that of the first partition wall layer L1. In more detail, because an etch-rate of the first preliminary partition wall layer L1-I is greater than an etch-rate of the second preliminary partition wall layer L2-1, the first preliminary partition wall layer L1-I may be mainly etched. Accordingly, a side surface of the first partition wall layer L1 may be formed to be more recessed inward than a side surface of the second partition wall layer L2. A portion of the second partition wall layer L2 protruding more than the first partition wall layer L1 may be formed as a tip portion in the partition wall PW.

Referring to FIG. 6H, the operation of forming the second pixel-defining film PDL2 (e.g., see FIG. 6I), the partition wall PW, and the upper sacrificial pattern SP2 may include the operation of forming the second pixel-defining film PDL2 by etching the second preliminary pixel-defining film PDL2-I (e.g., see FIG. 6G). In the operation of forming the second pixel-defining film PDL2, the second preliminary pixel-defining film PDL2-I may be dry-etched by using the second photoresist layer PR2 as a mask. A portion of the second preliminary pixel-defining film PDL2-I not overlapping with the second photoresist layer PR2 may be etched to be removed, and another portion of the second preliminary pixel-defining film PDL2-I that is not etched and left over may be the second pixel-defining film PDL2. The second pixel opening OP-PDL2 of the second pixel-defining film PDL2 may be formed by the portion that is etched and removed. The second pixel opening OP-PDL2 may overlap with the second photo opening OP-PR2 of the second photoresist layer PR2.

The first pixel-defining film PDL1 and the second pixel-defining film PDL2 may be defined as the pixel-defining film PDL, and the first pixel opening OP-PDL1 and the second pixel opening OP-PDL2 may be defined as the light-emitting opening OP-E. The first pixel-defining film PDL1 may include a first inner side surface S1-PDL defining the first pixel opening OP-PDL1. The second pixel-defining film PDL2 may include a second inner side surface S2-PDL defining the second pixel opening OP-PDL2.

Referring to FIG. 6I, the operation of forming the second pixel-defining film PDL2, the partition wall PW, and the upper sacrificial pattern SP2 may include the operation of forming the upper sacrificial pattern SP2 by etching the upper sacrificial layer SP2-I (e.g., see FIG. 6H). In the present disclosure, the upper sacrificial pattern SP2 may be referred to as a sacrificial pattern SP2. The operation of forming the upper sacrificial pattern SP2 by etching the upper sacrificial layer SP2-I may include the operation of forming the lower sacrificial pattern SP1 by etching the lower sacrificial layer SP1-I (e.g., see FIG. 6H).

In the operation of etching the upper sacrificial layer SP2-I, the upper sacrificial layer SP2-I may be wet-etched by using the second photoresist layer PR2 as a mask. In this case, the lower sacrificial pattern SP1 exposed by the light-emitting opening OP-E may be wet-etched together. Portions, of the lower sacrificial layer SP1-I and the upper sacrificial layer SP2-I not overlapping with the second photoresist layer PR2 may be etched to be removed, and other portions of the lower sacrificial layer SP1-I and the upper sacrificial layer SP2-I that are not etched to be left over may be the lower sacrificial pattern SP1 and the upper sacrificial pattern SP2, respectively. By the portion etched and removed, the upper sacrificial pattern SP2 may have the upper sacrificial opening OP-S2, and the lower sacrificial pattern SP1 may have the lower sacrificial opening OP-S1.

The upper sacrificial layer SP2-I exposed and partially etched in the operation of wet-etching the first preliminary partition wall layer L1-I (e.g., see FIG. 6F) and the second preliminary partition wall layer L2-I may be controlled to be less etched than the lower sacrificial layer SP1-I. For example, the upper sacrificial layer SP2-I may be zinc-indium-tin oxide (ZITO) doped with tin (Sn) of about 3 at % to about 14 at %, and the lower sacrificial layer SP1-I may be zinc-indium-tin oxide (ZITO) doped with tin (Sn) of about 15 at % to about 22 at %. Accordingly, an etch-rate of the lower sacrificial layer SP1-I may be controlled to be greater than an etch-rate of the upper sacrificial layer SP2-1.

The partition wall opening OP-P and the upper sacrificial opening OP-S2 may include a first region A1, a second region A2, and a third region A3. The partition wall opening OP-P may include the first region A1 and the third region A3, and the upper sacrificial opening OP-S2 may include the second region A2. The first to third regions A1, A2, and A3 may be integrally formed with each other in a thickness direction (e.g., the third direction DR3) of the base layer BL. A width of the second region A2 in the first direction DR1 may be greater than a width of the first region A1 in the first direction DR1 and a width of the third region A3 in the first direction DR1.

The first partition wall layer L1 may include the first side surface S1 (e.g., see FIG. 5) defining the first region A1. The upper sacrificial pattern SP2 may include the second side surface S2 (e.g., see FIG. 5) defining the second region A2. The second partition wall layer L2 may include the third side surface S3 (e.g., see FIG. 5) defining the third region A3. The second side surface S2 of the upper sacrificial pattern SP2 may be recessed, in a direction getting farther from the partition wall opening OP-P, more than the first side surface S1 of the first partition wall layer L1 and the third side surface S3 of the second partition wall layer L2. On a plane (e.g., in a plan view), the second side surface S2 of the upper sacrificial pattern SP2 may overlap with the first partition wall layer L1 and the second partition wall layer L2.

Referring to FIG. 6J, the method for manufacturing a display panel according to one or more embodiments of the present disclosure may include the operation of forming the light-emitting pattern EP in the partition wall opening OP-P and the operation of forming the cathode CE, after removing the second photoresist layer PR2.

The operation of forming the light-emitting pattern EP may be performed by a deposition process. For example, the operation of forming the light-emitting pattern EP may include a thermal evaporation process. The light-emitting pattern EP may be formed on the anode AE. In the operation of forming the light-emitting pattern EP, the light-emitting pattern EP may be separated by the tip portion formed in the partition wall PW to be disposed in the light-emitting opening OP-E and the partition wall opening OP-P. In the operation of forming the light-emitting pattern EP, a first dummy layer D1-I spaced apart from the light-emitting pattern EP may be formed on the partition wall PW together.

The operation of forming the cathode CE may be performed by a deposition process. For example, the operation of forming the cathode CE may include a sputtering process. The cathode CE may be formed on the light-emitting pattern EP. The cathode CE may be formed so as to be in contact with the partition wall PW, and so as to be spaced apart from the upper sacrificial pattern SP2. For example, the cathode CE may be formed so as to be in contact with a side surface of the first partition wall layer L1 by being supplied at a higher incident angle than that of the light-emitting pattern EP. In the operation of forming the cathode CE, the cathode CE may be separated by the tip portion formed in the partition wall PW to be disposed in the partition wall opening OP-P. In the operation of forming the cathode CE, a second dummy layer D2-I spaced apart from the cathode CE may be formed on the partition wall PW together. The anode AE, the light-emitting pattern EP, and the cathode CE may constitute the light-emitting element ED.

In addition, the method for manufacturing a display panel according to an embodiment may further include an operation of forming the capping pattern CP on the cathode CE. The operation of forming the capping pattern CP may be performed by a deposition process. For example, the operation of forming the capping pattern CP may include a thermal evaporation process. In the operation of forming the capping pattern CP, the capping pattern CP may be separated by the tip portion formed in the partition wall PW to be disposed in the partition wall opening OP-P. In the operation of forming the capping pattern CP, a third dummy layer D3-I spaced apart from the capping pattern CP may be formed on the partition wall PW together. According to another embodiment of the present disclosure, the operation of forming the capping pattern CP may be omitted as needed or desired.

However, the present disclosure is not limited to the above-described process, and the deposition process of each of the operation of forming the light-emitting pattern EP, the operation of forming the cathode CE, and the operation of forming the capping pattern CP is not limited thereto. The first to third dummy layers D1-1, D2-I, and D3-I may form a dummy layer DMP-I, and a dummy opening OP-D may be formed in the dummy layer DMP-I.

Referring to FIGS. 6J and 6K, the method for manufacturing a display panel according to one or more embodiments of the present disclosure may include an operation of forming the inorganic lower encapsulation pattern LIL.

As illustrated in FIG. 6J, the operation of forming the inorganic lower encapsulation pattern LIL (e.g., see FIG. 6K) may include an operation of depositing an inorganic lower encapsulation layer LIL-I. The inorganic lower encapsulation layer LIL-I may be formed through a deposition process. In an embodiment, the inorganic lower encapsulation layer LIL-I may be formed through a chemical vapor deposition (CVD) process.

The inorganic lower encapsulation layer LIL-I may be deposited on the partition wall PW and the cathode CE. In more detail, a portion of the inorganic lower encapsulation layer LIL-I may be deposited in the partition wall opening OP-P and the upper sacrificial opening OP-S2, and another portion of the inorganic lower encapsulation layer LIL-I may be deposited on the partition wall PW. The inorganic lower encapsulation layer LIL-I may be formed to be in contact with the upper sacrificial pattern SP2.

Referring to FIG. 6K, the method for manufacturing a display panel according to one or more embodiments of the present disclosure may include an operation of forming a third photoresist layer PR3, and an operation of patterning the inorganic lower encapsulation layer LIL-I (e.g., see FIG. 6J) and the dummy layer DMP-I so as to respectively form the inorganic lower encapsulation pattern LIL and the dummy patterns DMP.

In the operation of forming the third photoresist layer PR3, after a preliminary photoresist layer is formed, the third photoresist layer PR3 may be formed by patterning the preliminary photoresist layer using a photomask. Through the patterning process, the third photoresist layer PR3 may be formed in a form of a pattern corresponding to the light-emitting opening OP-E.

In the operation of patterning the inorganic lower encapsulation layer LIL-I, the inorganic lower encapsulation layer LIL-I may be dry-etched to be patterned so as to remove a portion of the inorganic lower encapsulation layer LIL-I overlapping with the rest except for a corresponding anode AE. The inorganic lower encapsulation pattern LIL overlapping with a corresponding light-emitting opening OP-E may be formed from the patterned inorganic lower encapsulation layer LIL-I.

In the operation of patterning the dummy layers DMP-I, the first to third dummy layers D1-1, D2-I, and D3-I may be dry-etched to be patterned so as to remove a portion of the first to third dummy layers D1-1, D2-1, and D3-I overlapping with the rest except for the corresponding anode AE.

The first to third dummy patterns D1, D2, and D3 overlapping with the corresponding light-emitting opening OP-E may be formed from the patterned first to third dummy layers D1-1, D2-1, and D3-I so that the dummy patterns DMP including the first to third dummy patterns D1, D2, and D3 may be formed. The first to third dummy patterns D1, D2, and D3 may have a closed line shape surrounding (e.g., around a periphery of) the corresponding light-emitting region PXA (e.g., see FIG. 4) on a plane (e.g., in a plan view).

In another embodiment of the present disclosure, the method for manufacturing a display panel may further include an operation of additionally etching the dummy patterns DMP. For example, in the operation of additionally etching the dummy patterns DMP, the dummy patterns DMP may be wet-etched to be removed.

Referring to FIG. 6L, the method for manufacturing a display panel according to one or more embodiments may include an operation of completing the display panel DP by forming the organic encapsulation film OL and the inorganic upper encapsulation film UIL after removing the third photoresist layer PR3 (e.g., see FIG. 6K). The organic encapsulation film OL may be formed by applying an organic material in an inkjet method, but the present disclosure is not limited thereto. The organic encapsulation film OL supplies a flat or substantially flat upper surface. The inorganic upper encapsulation film UIL may be formed by depositing an inorganic material. As such, the display panel DP including the base layer BL, the circuit element layer DP-CL, the display element layer DP-OLED, and the thin-film encapsulation layer TFE may be formed.

An operation of forming a partition wall opening and a light-emitting opening corresponding to a light-emitting region for supplying another color in the partition wall PW and the pixel-defining film PDL, an operation of forming light-emitting elements supplying the other color, and an operation of forming an inorganic lower encapsulation pattern that covers the light-emitting elements supplying the other color may be further performed between the operation of forming the inorganic lower encapsulation pattern LIL and the operation of completing the display panel DP. As such, the display panel DP including the first to third light-emitting elements, (1-1)-th to (1-3)-th dummy patterns, (2-1)-th to (2-3)-th dummy patterns, (3-1)-th to (3-3)-th dummy patterns, and first to third inorganic lower encapsulation patterns respectively corresponding to the plurality of light-emitting regions PXA-R, PXA-G, and PXA-B illustrated in FIG. 4 may be formed.

According to one or more embodiments described above, because an upper sacrificial pattern may be formed between a first partition wall layer and a second partition wall layer, a path through which foreign matters introduced from a side surface of an inorganic lower encapsulation pattern can pass may extend. In addition, because the upper sacrificial pattern has an undercut shape with respect to the first partition wall layer and the second partition wall layer, a cathode may be spaced apart from the upper sacrificial pattern. Accordingly, the upper sacrificial pattern including a transparent conductive oxide may be in direct contact with the inorganic lower encapsulation pattern, and a binding force between the inorganic lower encapsulation pattern and a partition wall may be improved, thereby reducing or removing a pixel defect (e.g., a dark point, a pixel shrinkage, or the like).

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display panel comprising:
a base layer;
a pixel-defining film on the base layer, and having a light-emitting opening;
a partition wall having a partition wall opening overlapping with the light-emitting opening, and comprising a first partition wall layer on the pixel-defining film, and a second partition wall layer on the first partition wall layer;
a light-emitting element at least partially located in the partition wall opening, and comprising an anode, an intermediate layer, and a cathode in contact with the partition wall; and
a sacrificial pattern between the first partition wall layer and the second partition wall layer, and having a sacrificial opening overlapping with the partition wall opening.

2. The display panel of claim 1, wherein the sacrificial pattern has an undercut shape with respect to the partition wall.

3. The display panel of claim 1, wherein the first partition wall layer of the partition wall has an undercut shape with respect to the second partition wall layer.

4. The display panel of claim 1, wherein the first partition wall layer comprises a first side surface defining a first region,
the sacrificial pattern comprises a second side surface defining a second region,
the second partition wall layer comprises a third side surface defining a third region, and
the first to third regions are integral with each other in a thickness direction of the base layer.

5. The display panel of claim 4, wherein the second side surface of the sacrificial pattern is recessed in a direction away from the partition wall opening more than the first side surface of the first partition wall layer and the third side surface of the second partition wall layer.

6. The display panel of claim 4, wherein in a plan view, the second side surface of the sacrificial pattern overlaps with the first partition wall layer and the second partition wall layer.

7. The display panel of claim 4, wherein a width of the second region in a first direction is greater than a width of the first region in the first direction and a width of the third region in the first direction.

8. The display panel of claim 1, further comprising a lower sacrificial pattern between the anode and the pixel-defining film, and having a lower sacrificial opening overlapping with the light-emitting opening.

9. The display panel of claim 1, wherein the pixel-defining film comprises:
a first pixel-defining film on the base layer, and comprising a first inner side surface defining a first pixel opening of the light-emitting opening; and
a second pixel-defining film on the first pixel-defining film, and comprising a second inner side surface defining a second pixel opening of the light-emitting opening.

10. The display panel of claim 9, wherein a width of the first pixel opening in a first direction is equal to or smaller than a width of the second pixel opening in the first direction.

11. The display panel of claim 1, wherein the cathode is spaced from the sacrificial pattern.

12. A display panel comprising:
a base layer;
a pixel-defining film on the base layer, and having a light-emitting opening;
a partition wall having a partition wall opening overlapping with the light-emitting opening, and comprising a first partition wall layer on the pixel-defining film, and a second partition wall layer on the first partition wall layer;
a light-emitting element at least partially located in the partition wall opening, and comprising an anode, an intermediate layer, and a cathode in contact with the partition wall;
a sacrificial pattern between the first partition wall layer and the second partition wall layer, and comprising a transparent conductive oxide; and
a lower sacrificial pattern between the anode and the pixel-defining film, and comprising a transparent conductive oxide.

13. The display panel of claim 12, wherein the lower sacrificial pattern has a lower sacrificial opening overlapping with the light-emitting opening, and
the sacrificial pattern has a sacrificial opening overlapping with the partition wall opening.

14. The display panel of claim 12, wherein the sacrificial pattern has an undercut shape with respect to the partition wall.

15. The display panel of claim 12, wherein the first partition wall layer comprises a first side surface defining a first region,
the sacrificial pattern comprises a second side surface defining a second region,
the second partition wall layer comprises a third side surface defining a third region,
the first to third regions are integral with each other in a thickness direction of the base layer, and
the second side surface of the sacrificial pattern is recessed in a direction away from the partition wall opening more than the first side surface of the first partition wall layer and the third side surface of the second partition wall layer.

16. The display panel of claim 15, wherein in a plan view, the second side surface of the sacrificial pattern overlaps with the first partition wall layer and the second partition wall layer.

17. The display panel of claim 12, wherein the cathode is spaced from the sacrificial pattern.

18. A method for manufacturing a display panel, the method comprising:
providing a preliminary display panel comprising a base layer, and an anode, a lower sacrificial layer, and a first preliminary pixel-defining film disposed on the base layer;
forming a first pixel-defining film by etching the first preliminary pixel-defining film;
sequentially depositing, on the first pixel-defining film, a second preliminary pixel-defining film, a first preliminary partition wall layer, a sacrificial layer, and a second preliminary partition wall layer; and
forming a second pixel-defining film, a partition wall, and a sacrificial pattern by etching the second preliminary pixel-defining film, the first preliminary partition wall layer, the sacrificial layer, and the second preliminary partition wall layer.

19. The method of claim 18, wherein the forming of the second pixel-defining film, the partition wall, and the sacrificial pattern comprises:
etching the second preliminary partition wall layer;
etching the sacrificial layer;
etching the first preliminary partition wall layer;
forming the partition wall having a partition wall opening by etching the first preliminary partition wall layer and the second preliminary partition wall layer;
forming the second pixel-defining film by etching the second preliminary pixel-defining film; and
forming the sacrificial pattern by etching the sacrificial layer.

20. The method of claim 19, wherein the forming of the sacrificial pattern by etching the sacrificial layer comprises forming a lower sacrificial pattern by etching the lower sacrificial layer.

21. The method of claim 19, further comprising:
forming a light-emitting pattern in the partition wall opening;
forming, in the partition wall opening, a cathode in contact with the partition wall and spaced from the sacrificial pattern; and
forming an inorganic lower encapsulation pattern in contact with the sacrificial pattern.
